(19) United States
(12) Patent Application Publication
(10) Pub. No.: US 2005/0146923 A1
(43) Pub. Date: Jul. 7, 2005

(54) Polymer/metal interface with multilayered diffusion barrier

(76) Inventors: Daniel C. Diana, Portland, OR (US); Douglas E. Janousek, Portland, OR (US); Ebrahim Andideh, Portland, OR (US); Mark R. Richards, Tigard, OR (US); Hitesh Windlass, Hillsboro, OR (US); Michael A. Deangelis, Portland, OR (US)

Correspondence Address: TROP PRUNER & HU, PC, 8554 KATY FREEWAY, SUITE 100, HOUSTON, TX, 77024, US

(21) Appl. No.: 10/746,173

(22) Filed: Dec. 24, 2003

(51) Int. Cl. G11C 11/00

(52) U.S. Cl. 365/154

(57) ABSTRACT

By using a plurality of relatively thin stacked diffusion layers interposed between a conductive line and a polymer layer, the diffusion of contaminates into a polymer layer from the conductive line may be reduced. This may reduce part failure during fatigue or disturb testing, for example, in ferroelectric polymer memories.

### BACKGROUND

This invention relates generally to electronic devices with polymer to metal interfaces.

A ferroelectric polymer memory may be used to store data. Data may be stored in layers within the memory. The higher the number of layers, the higher capacity of the memory. The polymer layers include polymer chains with dipole moments. Data may be stored by changing the polarization of the polymer between metal lines. No transistors may be needed for storage.

Ferroelectric polymer memories are non-volatile memories with sufficiently fast read and write speeds. For example, microsecond initial reads may be possible with write speeds comparable to those with flash memories.

Conventionally, polymer memories are formed by a layer of polymer between upper and lower parallel electrodes. Thus, successive, vertically spaced sets of horizontal and vertical lines may be utilized to define a polymer memory cell as a pixel at each orthogonal intersection of the upper and lower lines in the array. During electrical, e.g. fatigue and disturb testing at temperatures of 60° C. and higher, the metal-ferroelectric polymer metal structures tend to fail.

Thus, there is a need for alternate ways to interface polymer and metal in electronic devices.

### BRIEF DESCRIPTION OF THE DRAWINGS

FIG. 1 is a top plan view of one embodiment of the present invention;

FIG. 2 is a cross-sectional view taken generally along the line 2-2 in FIG. 1;

FIG. 3 is a cross-sectional view taken generally along the line 3-3 in FIG. 2;

FIG. 4 is a cross-sectional view taken generally along the line 4-4 in FIG. 2; and

FIG. 5 is a system depiction of one embodiment of the present invention.

### DETAILED DESCRIPTION

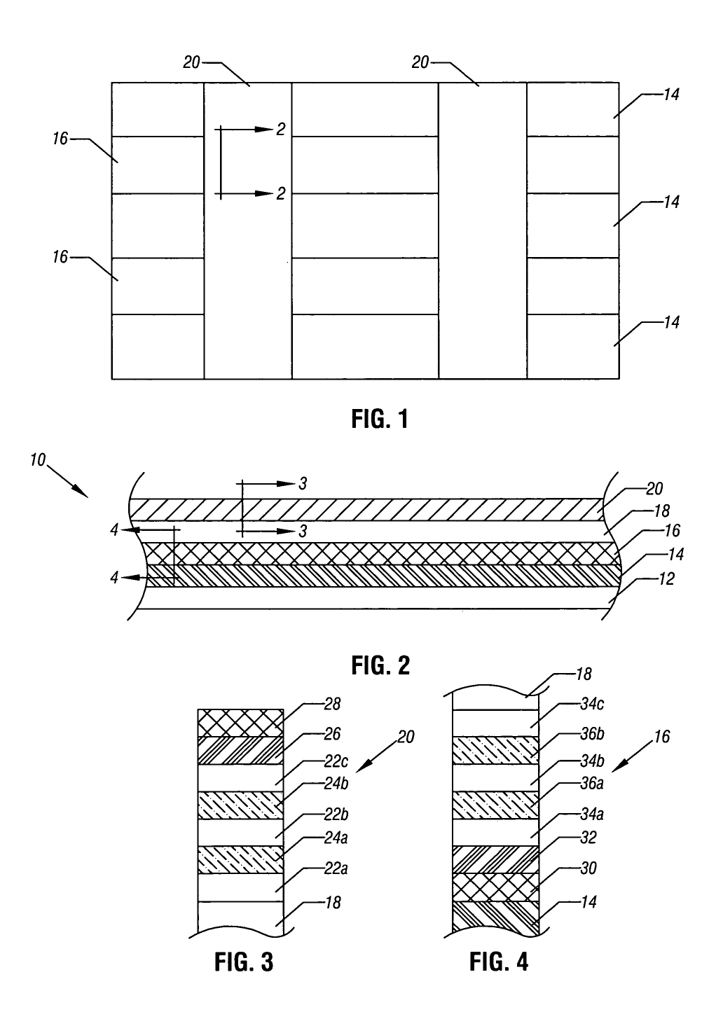

Referring to FIG. 1, a polymer memory, such as a ferroelectric polymer memory, may have spaced conductive lines 20 arranged substantially transversely to spaced conductive lines 16. The lines 16 and 20 may be formed of one or more metals in one embodiment of the present invention.

Referring to FIG. 2, the lines 20 may be formed over a polymer layer 18, in turn formed over a line 16. The lines 16 may be formed over an insulator 14, such as a thermal silicon dioxide material. Finally, substrate 12 (e.g. a silicon wafer) may be located below the other layers.

A stack 10 may be composed of many layers that suit specific purposes. While only one line 16 and 20 is shown, in some embodiments many successive rows, columns, and polymer layers may be utilized.

Referring to FIG. 3, a line 20 may be formed of a number of diffusion barrier layers 22, 24 over the polymer layer 18. A first barrier layer 22a may be formed on the layer 18 in one embodiment of the present invention. Over the layer 22a may be a second barrier layer 24a. The second barrier layer 24a may be covered by another first barrier layer 22b. The first barrier layer 22b may in turn be covered by another second barrier layer 24b, which is in turn covered by another first barrier layer 22c.

A conductive layer 26 may be formed over the layer 22c. In one embodiment, this conductive layer 26 may be titanium covered by another conductive layer 28 such as an aluminum layer.

The diffusion barrier layers 22 and 24 may be formed of a material, such as titanium nitride, tantalum nitride, tantalum, TiOₓ (where x may be between 1 and 2), ruthenium, zirconium, aluminum, or aluminum oxide, to mention a few examples, that reduces encroachment by drift/diffusion into the polymer layer 18 from the conductive layers 26 and 28. It is postulated that the failure of metal-ferroelectric polymer structures in fatigue and disturb testing at temperatures of 60° C. and higher is due at least in part to metal drift/diffusion from the metal lines into the ferroelectric polymer. Hence, existing diffusion barrier films inadequately prevent metal encroachment into the polymer.

In some embodiments, it may be advantageous to use different materials to form the diffusion barrier layers 22 and 24. The stack 10 may then be formed by alternating the layers 22 and 24. The present invention is not limited to five layers 22 and 24; more or less layers may be used.

Some or all of the layers of the stack 10 shown in FIG. 3 may be relatively thin. For example, 20 to 50 Angstrom diffusion barrier layers 22, 24 may be utilized.

The columns 20 and rows 16 may be patterned using conventional lithography and etch processes. The polymer layer 18 may be spun-on and cured. The polymer layer 18 may, for example, be formed of a copolymer of vinylidene fluoride (VDF) and trifluoroethylene (TrFE) in one embodiment of the present invention.

Other materials can be used for the layer 18 as well, including ferroelectric and non-ferroelectric polymers, such as polyethylene fluoride, copolymers, and combinations thereof, polyacrylonitriles, copolymers thereof, and combinations thereof, or polyamides, copolymers thereof, and combinations thereof. The layer 14 may formed of thermal silicon oxide or polyimide, to mention two examples.

Referring to FIG. 4, the line 16 may be formed under the polymer layer 18 and may include a first barrier layer 34c, in one embodiment of the present invention, over a second barrier layer 36b. The second barrier layer 36b may be positioned over a first barrier layer 34b, which in turn is formed over another second barrier layer 36a. The second barrier layer 36a may be positioned over another first barrier layer 34a. Under the layer 34a is a first conductive layer 32 in one embodiment of the present invention, which in turn covers a second conductive layer 30. The second conductive layer 30 is again positioned over the insulator 14 in one embodiment of the present invention.

Of course, the number of first and second barrier layers may be increased or decreased in embodiments of the present invention. However, by providing successive, alternative barrier layers, the effectiveness of the diffusion barrier layers 34, 36 in reducing contamination of the polymer layer 18 may be increased.

In one embodiment, the first barrier layers 34 and 36 may be formed of titanium nitride, tantalum nitride, tantalum, TiOₓ (where x is between 1 and 2), ruthenium, zirconium, aluminum, or aluminum oxide, to mention a few examples. In some embodiments, it is desirable that the first and second barrier layers 34 and 36 be different materials. The layers 34 and 36 may be about 20 to about 50 Angstroms thick. The first conductive layer 32 may be titanium and the second conductive layer 30 may be aluminum in one embodiment of the present invention. The insulator 14 may be thermal silicon dioxide or polyimide, as examples.

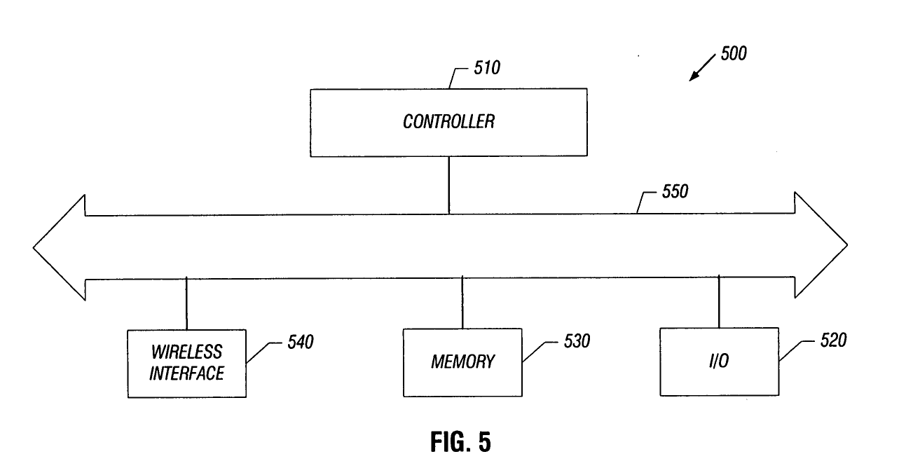

Referring to FIG. 5, a portion of a system 500, in accordance with one embodiment of the present invention, is illustrated. The system 500 may be used in a wireless device such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. The system 500 may be used in any of the following systems: a wireless local area network (WLAN) system, a wireless personal area network (WPAN) system, or a cellular network, although the scope of the present invention is not limited to these wireless or mobile systems or to wireless applications in general.

The system 500 may include a controller 510, an input/output (I/O) device 520 (e.g., a keypad, display), a memory 530, and a wireless interface 540 coupled to each other via bus 550. It should be noted that the scope of the present invention is not limited to embodiments having any or all of these components.

The controller 510 may comprise, for example, one or more microprocessors, digital signal processors, microcontrollers, or the like. The memory 530 may be used to store messages transmitted to or by the system 500. The memory 530 may also optionally be used to store instructions that are executed by the device 510 during the operation of the system 500, and may be used to store user data. The memory 530 may be provided by one or more different types of memory. For example, the memory 530 may comprise a volatile memory (any type of random access memory), a non-volatile memory, such as a flash memory, and/or a ferroelectric polymer memory of the type illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include a wireless transceiver or an antenna, such as a dipole antenna, although the scope of the present invention is not limited in this respect.

While examples of various materials useful in some embodiments of the present invention are mentioned, the scope of the present invention is not limited to the particular materials mentioned as illustrative examples.

Also, while a polymer memory is provided as one example, the present invention is also applicable to other electronic devices having polymer/metal interfaces. An example of such a device includes an organic light emitting diode.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. An electronic device comprising:
first and second conductive lines sandwiching a polymer layer; and
a stack of at least two diffusion barrier layers between at least one of said lines and said polymer layer.

2. The device of claim 1 wherein said conductive lines are formed of a metal.

3. The device of claim 2 wherein said metal is selected from the group including aluminum and titanium.

4. The device of claim 1 wherein said at least two diffusion barrier layers are different materials.

5. The device of claim 4 wherein said materials are selected from the group including titanium nitride, tantalum nitride, tantalum, titanium oxide, ruthenium, zirconium, aluminum, and aluminum oxide.

6. The device of claim 1 wherein said at least two diffusion barrier layers include a first set of at least two layers of different materials and a second set of at least two layers of said materials formed on said first set, said first and second sets acting as diffusion barriers.

7. The device of claim 1 including at least two diffusion barrier layers between a first conductive line and said polymer layer and at least two diffusion barrier layers between said second conductive line and said polymer layer.

8. The device of claim 7 including at least four barrier layers between said first conductive line and said polymer layer and at least four barrier layers between said second conductive line and said polymer layer.

9. The device of claim 1 wherein said first and second conductive lines are transverse to one another.

10. The device of claim 1 wherein said device is a polymer memory.

11. The device of claim 10 wherein said device is a ferroelectric polymer memory.

12. A method comprising:
forming a first conductive line;
forming a polymer layer; and
forming at least two diffusion barrier layers between said first conductive line and said polymer layer.

13. The method of claim 12 including forming said at least two diffusion barrier layers over said polymer layer.

14. The method of claim 12 including forming said two diffusion barrier layers under said polymer layer.

15. The method of claim 13 including forming a second conductive line over said second set of diffusion barrier layers between said polymer layer and said second conductive line.

16. The method of claim 12 including forming said at least two diffusion barrier layers of different materials.

17. The method of claim 16 including forming a second set of at least two diffusion barrier layers over said at least two diffusion barrier layers.

18. The method of claim 17 including alternating a diffusion barrier layer of a first material with a diffusion barrier layer of a second material to form a stack of at least four diffusion barrier layers.

19. The method of claim 12 including forming a polymer memory.

20. The method of claim 19 including forming a ferroelectric polymer memory.

21. A system comprising:
a controller;
a polymer memory coupled to said controller, said polymer memory including a first and second conductive line sandwiching a polymer material, at least two diffusion barrier layers between said first conductive line and said polymer material; and
a wireless interface.

22. The system of claim 21 including at least two diffusion barrier layers between said second conductive line and said polymer material.

23. The system of claim 22 wherein said first and second conductive lines are generally transverse to one another.

24. The system of claim 23 wherein at least four diffusion barrier layers are provided between said polymer material and said first conductive line and at least four diffusion barrier layers are provided between said second conductive line and said polymer material.

25. The system of claim 24 wherein two of said four diffusion barrier layers between said first conductive line and said polymer material are formed of a first material, and two of said layers are formed of a second material different from said first material.

26. The system of claim 25 wherein said materials are selected from the group including TiOₓ, titanium nitride tantalum nitride, tantalum, aluminum, aluminum oxide, ruthenium, and zirconium.

27. The system of claim 21 wherein said polymer memory is a ferroelectric polymer memory.

28. The system of claim 21 wherein said wireless interface includes a dipole antenna.
